(19) United States
(12) Patent Application Publication
(10) Pub. No.: US 2008/0093056 A1
(43) Pub. Date: Apr. 24, 2008

(54) THERMAL MODULE

(75) Inventors: CHING-BAI HWANG, Taipei Hsien (TW); JIN-GONG MENG, Shenzhen (CN); JIE ZHANG, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Taipei Hsien (TW)

(21) Appl. No.: 11/626,046

(22) Filed: Jan. 23, 2007

(30) Foreign Application Priority Data
Oct. 20, 2006 (CN) 200610063212.X

(51) Int. Cl. H05K 7/20

(52) U.S. Cl. 165/104.33; 165/80.3; 361/700

(57) ABSTRACT

A thermal module (100) includes a centrifugal blower (10) including a base plate (142), a top cover (16) and a sidewall (144) disposed between the base plate and the top cover and defining two air outlets (148a, 148b) therein; two fin assemblies (20a, 20b) are disposed at the air outlets of the centrifugal blower; two heat pipes (30, 40) are thermally connected with the fin assemblies and stacked along a height direction of the thermal module, which is substantially perpendicular to the base plate of the centrifugal blower. Each of the heat pipes thermally connects with a corresponding electronic component for transferring heat of the two electronic components to the two fin assemblies to be dissipated to ambient air.

### BACKGROUND OF THE INVENTION

1. Field of the Invention

The present invention relates generally to a thermal module, and more particularly to a thermal module for dissipating heat generated by electronic components.

2. Description of Related Art

With the fast development of the electronics industry, advanced electronic components such as CPUs (central processing units), or VGA (video graphics array) cards are being made with ever faster operating speeds. During operation of the advanced electronic components, a large amount of heat is generated. Greater emphasis is now being laid on increasing the efficiency and effectiveness of heat dissipation devices so as to keep operational temperature of the advanced electronic components within a suitable range. In laptop computers, the efficiency and effectiveness of the heat dissipation devices (thermal modules) for the advanced electronic components are more particularly considered.

In order to keep the operational temperature of the advanced electronic components of the laptop computer in the suitable range, a thermal module is used for dissipating heat generated by two major heat-generating advanced electronic components of the laptop computer, i.e., a CPU and a GPU (graphic processing unit). However, this kind of the thermal module occupies a large room of an inner space of the laptop computer, which results in the volume of the laptop computer being accordingly increased. This goes against the need for electric components with smaller volume. Furthermore, the heat dissipation capability of the conventional thermal module is not good enough to meet the more and more strict requirement of heat dissipation for the modern CPU and GPU. Therefore, a thermal module having a better heat dissipation efficiency but not increase the volume of the laptop computer is needed.

### SUMMARY OF THE INVENTION

The present invention relates to a thermal module for simultaneously dissipating heat generated by at least two heat-generating electronic components in an electronic device. According to a preferred embodiment of the present invention, the thermal module includes a centrifugal blower including a base plate, a top cover and a sidewall disposed between the base plate and the top cover and defining at least an air outlet therein; at least a fin assembly is disposed at the at least an air outlet of the centrifugal blower; at least two heat pipes are thermally connected with the at least a fin assembly and stacked along a direction substantially perpendicular to the base plate of the centrifugal blower. In other words, one of the at least two heat pipes is located between the base plate and the other one of the at least two heat pipes along a height direction of the thermal module.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a thermal module and two heat generating electronic components according to a preferred embodiment of the present invention;

FIG. 2 is a partly assembled view of the thermal module of FIG. 1;

FIG. 3 is an assembled view of the thermal module of FIG. 1; and

FIG. 4 is a side view of a second heat pipe of the thermal module of FIG. 1.

### DETAILED DESCRIPTION OF THE INVENTION

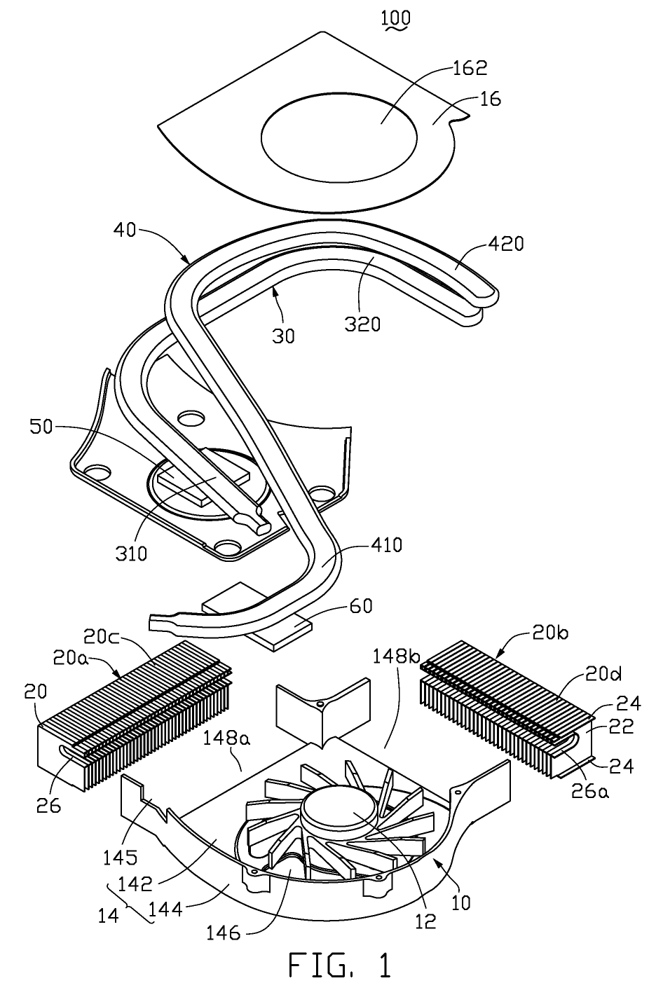

Referring to FIG. 1, a thermal module 100 according to a preferred embodiment of the present invention is shown. The thermal module 100 is used for dissipating heat generated by first and second heat generating electronic components 50, 60 of a portable electronic product such as a laptop computer, or a DVD player. In accordance with the preferred embodiment, the electronic component 50 is a CPU (central processing unit), while the electronic component 60 is a GPU (graphic processing unit) of a video graphics array (VGA) card of a laptop computer. The thermal module 100 includes a centrifugal blower 10, first and second fin assemblies 20a, 20b, and flattened first and second heat pipes 30, 40.

The centrifugal blower 10 is used to provide an airflow passing through the first and second fin assemblies 20a, 20b. The centrifugal blower 10 includes a bottom housing 14, a top cover 16 covering the bottom housing 14, a stator (not shown) mounted in a space formed between the bottom housing 14 and the top cover 16, and a rotor 12 rotatably disposed around the stator.

The top cover 16 is a planar plate, which defines a first air inlet 162 therein. The bottom housing 14 includes a flattened base plate 142 perpendicular to a rotational axis of the rotor 12, and an arc-shaped sidewall 144 perpendicular to the top cover 16 and the base plate 142 of the bottom housing 14. The base plate 142 of the bottom housing 14 defines a second air inlet 146 therein. The first and second electronic components 50, 60 are disposed at one side out of the sidewall 144 of the centrifugal blower 10. The sidewall 144 of the bottom housing 14 defines therein a linear-shaped first air outlet 148a and a linear-shaped second air outlet 148b perpendicular to the first air outlet 148a. The sidewall 144 defines a U-shaped opening 145 at one side of the first air outlet 148a so as to allow the first heat pipe 30 to extend therethrough.

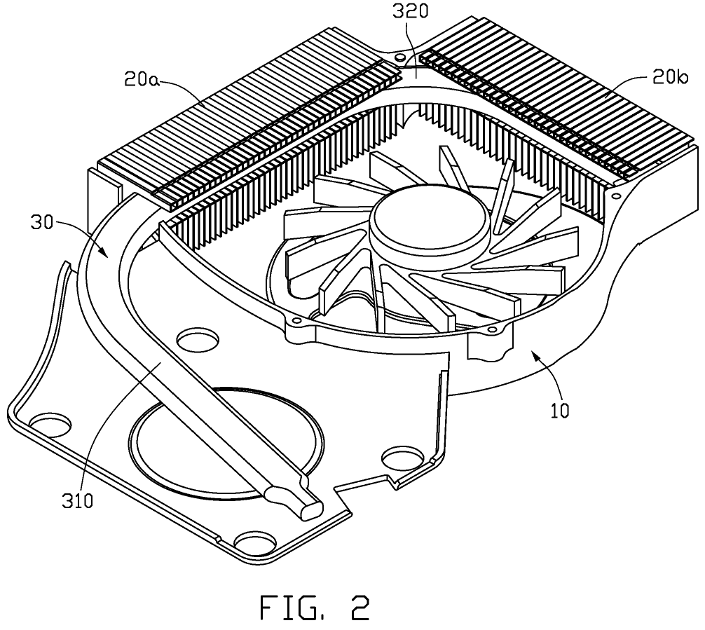

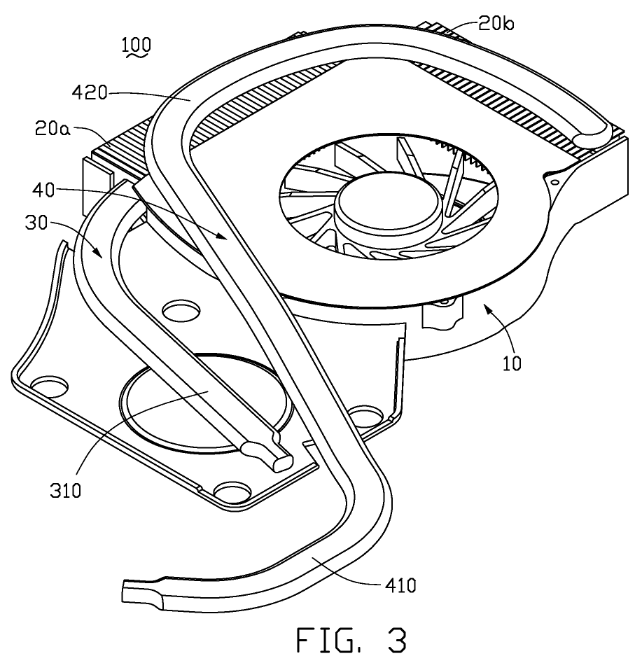

Referring also to FIGS. 2 and 3, the first and second fin assemblies 20a, 20b are respectively arranged at the first and second air outlets 148a, 148b of the centrifugal blower 10. The first and second fin assemblies 20a, 20b each include a plurality of stacked fins 20 and is linear-shaped in profile so as to match with the corresponding first and second air outlets 148a, 148b. Each of the fins 20 includes a rectangular-shaped main body 22 and two flanges 24 perpendicularly extending from top and bottom ends of the main body 22. The flanges 24 of a rear fin 20 abut against the main body 22 of a front fin 20 so as to form an air passage (not labeled) between two adjacent fins 20 and form two contacting surfaces 20c, 20d at tops of the first and second fin assemblies 20a, 20b respectively. The contacting surfaces 20c, 20d of the first and second fin assemblies 20a, 20b are coplanar with a top surface of the top cover 16 of the centrifugal blower 10. The main body 22 of each fin 20 defines a converted U-shaped cutout 26 therein at one side adjacent to the rotor 12 of the centrifugal blower 10. Each of the fins 20 further extends a collar 26a from a periphery of the cutout 26. The first heat pipe 30 extends through the U-shaped opening 145 of the sidewall 144 of the centrifugal blower 10, and is accommodated in the cutouts 26 and contacts with the collars 26a of the fins 20 of the first and second fin assemblies 20a, 20b. The collars 26a of the fins 20 increase contacting area between the first heat pipe 30 and the first and second fin assemblies 20a, 20b and therefore improving the heat transfer therebetween. Alternatively, the cutout 26 may be defined at an opposite side of each fin 20 distant from the rotor 12 of the centrifugal blower 10.

The first heat pipe 30 is substantially C-shaped in profile, whilst the second heat pipe 40 is substantially S-shaped in profile. The first and second heat pipes 30, 40 are arranged along a direction substantially perpendicular to the base plate 142 of the centrifugal blower 10. Each of the first and second heat pipes 30, 40 includes an evaporator section 310/410 and a condenser section 320/420. The condenser sections 320, 420 of the first and second heat pipes 30, 40 are bent to be L-shaped so as to simultaneously contact with the first and second fin assemblies 20a, 20b.

The evaporator section 310 of the first heat pipe 30 thermally connects with the first heat generating electronic component 50 so as to absorb heat therefrom. The condenser section 320 of the first heat pipe 30 is received in the cutouts 26 and thermally contacts the collars 26a of the fins 20 of the first and second fin assemblies 20a, 20b so as to transfer the heat generated by the CPU to the first and second fin assemblies 20a, 20b. The evaporator section 410 of the second heat pipe 40 thermally connects with the second heat generating electronic component 60 so as to absorb heat therefrom. The condenser section 420 of the second heat pipe 40 thermally contacts with the contacting surfaces 20c, 20d of the first and second fin assemblies 20a, 20b so as to transfer the heat generated by the second heat generating electronic component 60 to the first and second fin assemblies 20a, 20b. In order to make sure a good thermal contact between the condenser sections 320, 420 of the first and second heat pipes 30, 40 and the first and second fin assemblies 20a, 20b, a layer of thermal interface material is spread between the collars 26a of the fins 20 of first and second fin assemblies 20a, 20b and the condenser section 320 of the first heat pipe 30, and the contacting surfaces 20c, 20d of the first and second fin assemblies 20a, 20b and the condenser section 420 of the second heat pipe 40.

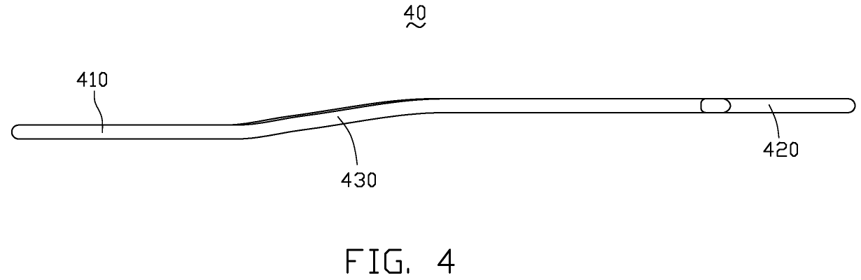

Referring to FIG. 4, the second heat generating electronic component 60 is disposed lower than the condenser section 420 of the second heat pipe 40. The second heat pipe 40 includes a bent portion 430 disposed between the evaporator section 410 and the condenser section 420 of the second heat pipe 40 so as to keep an intimate contact between the evaporator section 410 of the second heat pipe 40 and the second heat generating electronic component 60. The condenser section 420 is located at a level higher than that of the evaporator section 410. In addition, if the first heat generating electronic component 50 is lower than the condenser section 320 of the first heat pipe 30, there will also be a bent portion formed between the evaporator section 310 and the condenser section 320 of the first heat pipe 30 so as to keep an intimate contact between the evaporator section 310 of the first heat pipe 30 and the first heat generating electronic component 50.

In the present thermal module 100, the first and second heat pipes 30, 40 are arranged along the direction substantially perpendicular to the base plate 142 of the centrifugal blower 10, which increases the contact area between the first and second heat pipes 30, 40 and the first and second fin assemblies 20a, 20b compared to a conventional thermal module with two parallel heat pipes arranged on top surfaces of fin assemblies. By the design of the present invention: the condenser section 320 of the first heat pipe 30 is located between the condenser section 420 of the second heat pipe 40 and the base plate 142 along a height direction of the thermal module 100, the heat dissipation efficiency of the present thermal module 100 can be increased without increasing the volume of the thermal module 100. Moreover, the first and second heat pipes 30, 40 simultaneously contact with the respective flanges 24 and collars 26a of the first and second fin assemblies 20a, 20b. This further increases the contacting areas between the first and second heat pipes 30, 40 and the first and second fin assemblies 20a, 20b, therefore increasing the heat dissipating efficiency of the thermal module 100.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A thermal module comprising:
a centrifugal blower comprising a base plate, a top cover and a sidewall disposed between the base plate and the top cover and defining at least an air outlet therein;
at least a fin assembly disposed at the at least an air outlet of the centrifugal blower; and
at least two heat pipes thermally connected with the at least a fin assembly and stacked along a direction substantially perpendicular to the base plate of the centrifugal blower, the at least two heat pipes being for thermally connecting with at least two heat generating electronic components, respectively.

2. The thermal module as described in claim 1, wherein the at least two heat pipes comprises a first heat pipe and a second heat pipe, the first heat pipe extending through the at least a fin assembly and the second heat pipe contacting with a top side of the at least a fin assembly.

3. The thermal module as described in claim 1, wherein the sidewall of the centrifugal blower defines a U-shaped opening therein for extension of one of the at least two heat pipes therethrough.

4. The thermal module as described in claim 2, wherein each of the first and second heat pipes comprises an evaporator section, and the evaporator sections of the first and second heat pipes respectively contact with a first heat generating electronic component and a second heat generating electronic component.

5. The thermal module as described in claim 1, wherein at least one of the at least two heat pipes has a bent portion formed between an evaporator section and a condenser section thereof so that the condenser section is located at a level higher that that of the evaporator section.

6. The thermal module as described in claim 1, wherein the centrifugal blower comprises a rotor disposed in an inner space formed between the top cover, the bottom plate and the sidewall, the at least a fin assembly comprising a plurality of fins, each of the fins defining a cutout therein at a side adjacent to the rotor for accommodating a portion of one of the at least two heat pipes therein.

7. The thermal module as described in claim 6, wherein the cutout is converted U-shaped in profile, each of the fins extending a collar from a periphery of the cutout.

8. A thermal module configured for simultaneously dissipating heat generated by two heat generating electronic components, comprising:
a centrifugal blower comprising a base plate, a top cover and a sidewall disposed between the base plate and the top cover and defining at least an air outlet therein;
at least a fin assembly disposed at the at least an air outlet of the centrifugal blower; and
first and second heat pipes each comprising an evaporator section and a condenser section, the evaporator section of the first heat pipe being configured for thermally connecting with one of the heat generating electronic components, the condenser section of the first heat pipe being configured for extending through the at least a fin assembly, the evaporator section of the second heat pipe being configured for thermally connecting with the other one of the heat generating electronic components, the condenser section of the second heat pipe being configured for contacting with one side of the at least a fin assembly.

9. The thermal module as described in claim 8, wherein the centrifugal blower comprises a rotor disposed in an inner space formed between the top cover, the bottom plate and the sidewall, the first and second heat pipes being stacked along a direction substantially parallel to a rotation axis of the rotor of the centrifugal blower.

10. The thermal module as described in claim 8, wherein the at least an air outlet comprises two air outlets perpendicular to each other, the at least a fin assembly comprising two fin assemblies respectively disposed at the air outlets, the condenser sections of the first and second heat pipes being L-shaped in profile so as to simultaneously contact with the fin assemblies.

11. The thermal module as described in claim 8, wherein the one of the heat generating electronic components is a CPU for a laptop computer, and the other one of the heat generating electronic components is a GPU of a VGA card for the laptop computer.

12. The thermal module as described in claim 8, wherein the at least a fin assembly comprises a plurality of fins each defining a cutout therein and extending a collar from a periphery of the cutout, the condenser section of the first heat pipe being received in the cutouts and contacting with the collars of the fins, the condenser section of the second heat pipe contacting with a plurality of flanges extending from a top end of each fin.
